(19) United States
(12) Patent Application Publication
(10) Pub. No.: US 2011/0316073 A1
(43) Pub. Date: Dec. 29, 2011

(54) SOI CMOS DEVICE HAVING VERTICAL GATE STRUCTURE

(75) Inventors: Xinxong Cheng, Shanghai (CN); Dawei He, Shanghai (CN); Zhongjian Wang, Shanghai (CN); Dawei Xu, Shanghai (CN); Chao Xia, Shanghai (CN); Zhaorui Song, Shanghai (CN); Yuehui Yu, Shanghai (CN)

(73) Assignee: SHANGHAI INSTITUTE OF MICROSYSTEM AND INFORMATION TECHNOLOGY, CHINESE ACADEMY SCIENCES, Shanghai (CN)

(21) Appl. No.: 13/254,041

(22) PCT Filed: Dec. 15, 2010
(86) PCT No.: PCT/CN2010/079812

§ 371 Date: Aug. 31, 2011

(30) Foreign Application Priority Data
Dec. 24, 2009 (CN) 200910200721.6

(51) Int. Cl. H01L 27/12

(52) U.S. Cl. 257/329; 257/E27.112

(57) ABSTRACT

The present invention discloses an SOI CMOS device having a vertical gate structure, comprising: an SOI substrate, and an NMOS region and a PMOS region grown on the SOI substrate, wherein the NMOS region and the PMOS region share one vertical gate region, said vertical gate region lying in the same plane as the NMOS region and the PMOS region and between the NMOS region and the PMOS region; a gate oxide layer is arranged between the vertical gate region and the NMOS region for isolation; and a gate oxide layer is arranged between the vertical gate region and the PMOS region for isolation. The present invention occupies small area, contains less pattern layers, requires a simple process, has an open body region that can completely avoid the floating effect of the traditional SOI CMOS device, and is convenient to parasitic resistance and capacitance tests.

### FIELD OF THE INVENTION

The present invention relates to the technical fields of microelectronics and solid state electronics, and particularly, relates to an SOI CMOS device having a vertical gate structure.

### BACKGROUND OF THE INVENTION

A Complementary Metal Oxide Semiconductor (CMOS) is a semiconductor device which exhibits that n-type metal oxide semiconductor (NMOS) transistors and p-type metal oxide semiconductor (PMOS) transistors are integrated on one silicon wafer. As device sizes are continuously diminished, the short channel effect (SCE) becomes an intractable impediment which affects further diminishing of conventional planar CMOS devices pro rata, and results in degradation of device properties and increase of parasitic effects.

Silicon On Insulator (SOI) refers to replacing a traditional bulk-type silicon substrate with an “engineered” base, which generally consists of three layers: a layer of thin top poly silicon layer with circuits being etched thereon; a layer of extraordinary thin buried oxide (BOX) layer, i.e., insulating silicon dioxide intermediate layer; and a layer of extraordinary thick bulk-type silicon substrate which is mainly used to provide mechanical support for the two layers attached thereon. As in the SOI structure, the oxide layer isolates the silicon film thereon from the silicon substrate, a large area of p-n junctions will be replaced by dielectric isolation. By extending the source region and the drain region downwards to the BOX layer, leakage current and junction capacitance can be effectively reduced, and parasitic latch-up effects in bulk silicon CMOS device can be completely eliminated. Such a structure features a rapid speed, low power consumption, high integration, strong interference resistance, and the like, and therefore is applicable to the radio frequency field, the high voltage field, the anti-irradiation field, etc.

Due to the dielectric isolation of the SOI, the depletion layers at the upper Si-SiO₂ surface and the bottom Si-SiO₂ surface of an MOS device prepared on the thick-film SOI substrate do not contact each other, between which a neutral body region is formed. Such a neutral body region causes the silicon body to be electrically floating, which thereby generates two obvious secondary parasitic effects: one is the Kink effect; the other is the open-base NPN parasitic transistor effect existing between the source region and the drain region. The suspended body region results in an elevated electric potential, and therefore electric charge generated by collision ionization cannot be quickly removed, thereby forming the floating effect. The floating effect that particularly occurs in SOI CMOS devices will not only decrease the gain of the device, reduce the source and drain breakdown voltages, induce single transistor latch and relatively large leakage current, and thus increase the power consumption, but result in unstable operation of circuits and noise overshoot, which greatly affect the properties of the device and the circuits.

To address the floating effect brought by the SOI substrate, a body contact method is usually applied, which connects the “body” to a constant potential (source or ground). A traditional body contact structure is shown in FIGS. 1 and 2, in which P⁺ injection region formed on the left side of the source region is connected to the p-type body region under the source region. When the MOS device operates, current carriers accumulated in the body region are discharged via the P⁺ channel so as to reduce the electric potential of the body region. However, this method is complicated in its process, which increases the parasitic effects, reduces partial electric properties, and enlarges the area of the device.

### SUMMARY OF THE INVENTION

An objective of the present invention is to provide an SOI CMOS device having a vertical gate structure, which can avoid the floating effects that occurs in traditional SOI CMOS devices.

To achieve said objective, the present invention adopts the following technical solution.

An SOI CMOS device having a vertical gate structure, comprising: an SOI substrate, and an NMOS region and a PMOS region grown on the SOI substrate, wherein the NMOS region and the PMOS region share one vertical gate region that lies in the same plane as the NMOS region and the PMOS region and lies between the NMOS region and the PMOS region; a gate oxide layer is formed between the vertical gate region and the NMOS region for isolation; and a gate oxide layer is formed between the vertical gate region and the PMOS region for isolation.

In a preferred technical solution of the present invention, the SOI substrate consists of a silicon substrate grown from bottom up, a BOX layer, and a top poly silicon layer.

In another preferred technical solution of the present invention, the gate oxide layer extends downwards to the BOX layer, and a BOX layer is formed between the vertical gate region and the silicon substrate, between the NMOS region and the silicon substrate, and between the PMOS and the silicon substrate.

In another preferred technical solution of the present invention, the NMOS region consists of an NMOS source region, an NMOS drain region, and an NMOS trench. An NMOS source is led out from the NMOS source region, an NMOS drain is led out from the NMOS drain region, and an NMOS electrode is led out of the NMOS trench.

In another preferred technical solution of the present invention, the PMOS region consists of a PMOS source region, a PMOS drain region, and a PMOS trench. A PMOS source is led out from the PMOS source region, a PMOS drain is led out from the PMOS drain region, and a PMOS electrode is led out of the PMOS trench.

In another preferred technical solution of the present invention, the vertical gate region is vertically aligned with the NMOS trench and the PMOS trench.

In another preferred technical solution of the present invention, a gate is led out of the vertical gate region.

In another preferred technical solution of the present invention, an NMOS protective layer is grown on the NMOS region, and a PMOS protective layer is grown on the PMOS region.

The present invention has the following advantages: it occupies small area, contains less pattern layers, requires a simple process, has an open body which can completely avoid the floating effect that readily occurs in the traditional SOI CMOS devices, and is convenient to parasitic resistance and capacitance tests.

### BRIEF DESCRIPTION OF THE DRAWINGS

FIG. 1 is a top view of a body contact region;

FIG. 2 is a cross section of the body contact region;

FIG. 3 is a three-dimensional schematic diagram of the present invention;

FIG. 4 is a cross-sectional schematic diagram of the present invention in the x-z axis direction;

FIG. 5 is a cross-sectional schematic diagram of the NMOS of the present invention in the y-z axis direction;

FIG. 6 is a top view of the present invention; and

FIG. 7 is a schematic diagram of the process for fabricating a gate oxide layer according to the present invention.

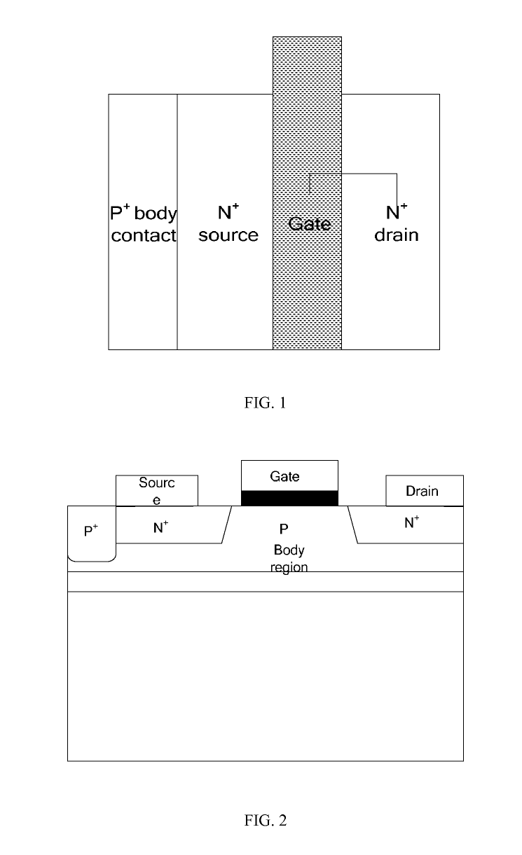

Sign references for primary components are described as follows:

| | | | |
|---|---|---|---|
| 1 | Source region of the NMOS | 2 | NMOS trench |
| 3 | Drain region of the NMOS | 4 | NMOS gate oxide layer |
| 5 | Vertical gate region | 6 | PMOS gate oxide layer |
| 7 | Drain region of the PMOS | 8 | PMOS trench |
| 9 | Source region of the PMOS | 10 | BOX layer |
| 11 | Silicon substrate | 12 | NMOS electrode |
| 13 | PMOS electrode | 14 | NMOS drain |
| 15 | PMOS drain | 16 | NMOS source |
| 17 | PMOS source | 18 | Gate |
| 19 | NMOS protective layer | 20 | PMOS protective layer |

### DETAILED DESCRIPTION OF THE EMBODIMENTS

The present invention will be detailed hereinafter with reference to the attached drawings.

In order to eliminate the floating effect that readily occurs in the SOI CMOS devices, the present invention put forwards a novel SOI CMOS device having a vertical gate structure, in which an electrode is introduced to clamp the electric potential of the body region, and the electric potential can be connected to the ground or the source as required, thereby almost completely eliminating the floating effect in the SOI CMOS devices.

### Embodiment 1

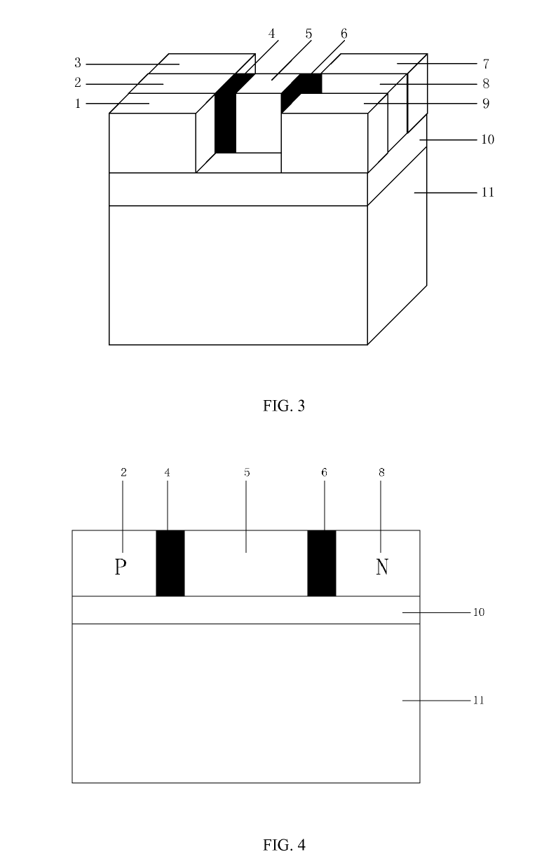

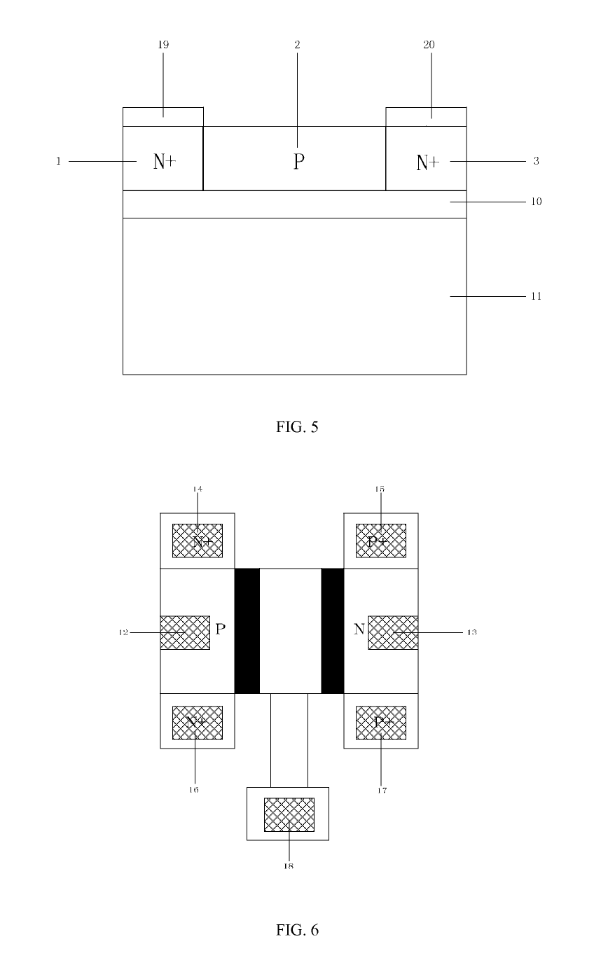

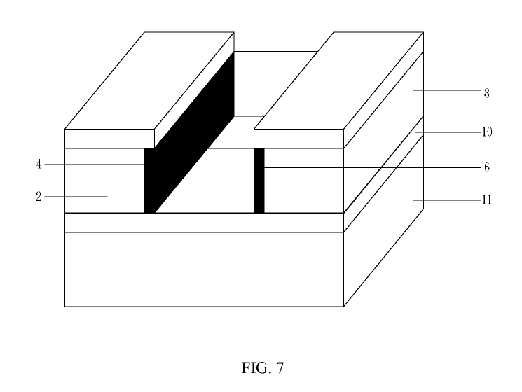

As shown in FIGS. 3 to 7, this embodiment provides an SOI CMOS device having a vertical gate structure, comprising an SOI substrate, and an NMOS region and a PMOS region grown on the SOI substrate. The NMOS region and the PMOS region share one vertical gate region 5 which lies in the same plane as the NMOS region and the PMOS region and lies between the NMOS region and the PMOS region. Between the vertical gate region 5 and the NMOS region is formed an NMOS gate oxide layer 4 for isolation, and between the vertical gate region 5 and the PMOS region is formed an PMOS gate oxide layer 6 for isolation.

The SOI substrate comprises a silicon substrate 11 grown from bottom up, a BOX layer 10, and top poly silicon layer. Both the NMOS gate oxide layer 4 and the PMOS gate oxide layer 6 extend downwards to the BOX layer 10 which is formed between the vertical gate region 5 and the silicon substrate 11, between the NMOS region and the silicon substrate 11, and between the PMOS region and the silicon substrate 11 for isolation. The NMOS region comprises an NMOS source region 1, an NMOS drain region 3, and an NMOS trench 2. An NMOS source 16 is led out of the NMOS source region 1, an NMOS drain 14 is led out of the NMOS drain region 3, and an NMOS electrode 12 is led out of the NMOS trench 2. The PMOS region consists of a PMOS source region 9, a PMOS drain region 7, and a PMOS trench 8. A PMOS source 17 is led out of the PMOS source region 9, a PMOS drain 15 is led out of the PMOS drain region 7, and a PMOS electrode 13 is led out of the PMOS trench 8. A gate 18 is led out of the vertical gate region 5. The vertical gate region 5 is vertically aligned with the NMOS trench 2 and the PMOS trench 8. In the NMOS region, an NMOS protective layer 19 is grown, and in the PMOS region, a PMOS protective layer 20 is grown.

The SOI CMOS device having a vertical gate structure that can eliminate the floating effects readily occurring in the SOI CMOS device as provided by the present invention mainly comprises: an SOI substrate, a PMOS region having P trenches, an NMOS region having N trenches, and a vertical gate region, wherein the PMOS region and the NMOS region share one vertical gate region which lies between the PMOS region and the NMOS region in the horizontal direction; the vertical gate region extends to the BOX layer, and parallels the PMOS trench and the NMOS trench in the horizontal direction; a BOX layer is arranged between the PMOS region or the NMOS region and the silicon substrate for isolation therebetween. Such an SOI CMOS device having a vertical gate structure occupies less area, contains less pattern layers, requires a simple process, has an open body region that can completely avoid the floating effect that readily occurs in traditional SOI CMOS devices, and is convenient to parasitic resistance and capacitance tests.

### Embodiment 2

This embodiment provides a method for fabricating an SOI CMOS device having a vertical gate structure, mainly comprising the following steps:

1. The shallow trench isolation (STI) technology is used to realize oxide isolation between the PMOS region and the NMOS region.

2. A window is etched between the PMOS region and the NMOS region and the remaining part is protected with silicon nitride. Then, the side wall is oxidized via thermal oxidation to form the gate oxide layers of the PMOS and the NMOS. Further, polycrystalline silicon is deposited and doped, and only the polycrystalline silicon at the window is retained after chemical mechanical polishing (CMP) for planarization.

3. Trenches of NMOS and the PMOS regions are doped by multiple ion implantations. After doping, annealing proceeds as quickly as possible, and the vertical depth can be controlled by adjusting the implantation energy and the dosage. Cross-sectional impurities after doping should be distributed uniformly, and the impurities at the edges should be distributed clearly abruptly.

4. The source regions and the drain regions of the NMOS region and the PMOS region are heavily doped via ion implantation, and annealing proceeds as quickly as possible after doping.

5. Windows are etched respectively on the trenches, source regions, drain regions, and vertical gate regions of the PMOS region and the NMOS region, and then the metal is deposited to lead out the electrodes, sources, drains, and gates, wherein the electrodes can be connected to the ground or the source as required.

The method for fabricating an SOI CMOS device having a vertical gate structure comprises the following steps:

Step 1: A silicon substrate, a BOX layer, and top poly silicon layer are grown in sequence from bottom up to constitute the SOI substrate.

Step 2: The integrated-circuit STI technology is used to prepare oxide isolation in the active region that is formed at the top poly silicon layer on the SOI substrate, wherein the active region comprises an NMOS region and a PMOS region.

Step 3: A window is etched between the NMOS region and the PMOS region, and an NMOS gate oxide layer and a PMOS gate oxide layer are formed at the inner side wall of the window via thermal oxidation. The NMOS region comprises an NMOS source region, an NMOS drain region, and an NMOS trench; the PMOS region comprises a PMOS source region, a PMOS drain region, and a PMOS trench.

Step 4: Polycrystalline silicon is deposited, stuffed, and doped at the window, and a vertical gate region is formed with the CMP technology.

Step 5: The NMOS trench and the PMOS trench are doped via multiple ion implantations, and annealing proceeds as quickly as possible after doping.

Step 6: The NMOS source region, the NMOS drain region, the PMOS source region, and the PMOS drain region are heavily doped via ion implantation, and annealing proceeds as quickly as possible after doping.

A metal is deposited respectively in the NMOS source region, NMOS drain region, and NMOS trench to lead out the NMOS source, NMOS drain, and NMOS electrode; and a metal is deposited respectively in the PMOS source region, PMOS drain region, and PMOS trench to lead out the PMOS source, PMOS drain, and PMOS electrode; a metal is deposited in the vertical gate region to lead out the gate.

In step 3, the device excluding the inner wall of the window is protected with photoresist. In step 5, vertical depths of the NMOS trench and the PMOS trench depend on the adjustable ion implantation energy and dosage, and cross-sectional impurities of the NMOS trench and the PMOS trench after doping are distributed uniformly and the impurities at the edges are distributed clearly abruptly.

The depiction and application of the present invention are just illustrative, but not intended to limit the scope of the present invention. Variations and changes of the embodiments disclosed herein are feasible, and individual replaceable and equivalent components used in the embodiments of the present invention are well known by those of ordinary skill in the art. Those skilled in the art shall clearly know that the present invention can be implemented in other forms, in other structures, in other layouts, in other proportions, and with other elements, materials, and components, without departing from the spirit or substantive characteristics of the present invention.

1. A SOI CMOS device having a vertical gate structure comprising: an SOI substrate, and an NMOS region and a PMOS region grown on the SOI substrate, wherein the NMOS region and the PMOS region share one vertical gate region, said vertical gate region lying in the same plane as the NMOS region and the PMOS region and between the NMOS region and the PMOS region; a gate oxide layer is arranged between the vertical gate region and the NMOS region for isolation; and a gate oxide layer is arranged between the vertical gate region and the PMOS region for isolation.

2. The SOI CMOS device having a vertical gate structure of claim 1, wherein the SOI substrate comprises a silicon substrate, a buried oxide layer, and a top poly silicon layer that are grown from bottom up.

3. The SOI CMOS device having a vertical gate structure of claim 2, wherein the gate oxide layer extends downwards to the BOX layer, and the BOX layer is arranged between the vertical gate region and the silicon substrate, between the NMOS region and the silicon substrate, and between the PMOS region and the silicon substrate.

4. The SOI CMOS device having a vertical gate structure of claim 1, wherein the NMOS region comprises an NMOS source region, an NMOS drain region, and an NMOS trench; an NMOS source is led out from the NMOS source region, an NMOS drain is led out from the NMOS drain region, and an NMOS electrode is led out of the NMOS trench.

5. The SOI CMOS device having a vertical gate structure of claim 1, wherein the PMOS region comprises a PMOS source region, a PMOS drain region, and a PMOS trench; a PMOS source is led out from the PMOS source region, a PMOS drain is led out from the PMOS drain region, and a PMOS electrode is led out of the PMOS trench.

6. The SOI CMOS device having a vertical gate structure of claim 4, wherein the vertical gate region is vertically aligned with the NMOS trench and the PMOS trench.

7. The SOI CMOS device having a vertical gate structure of claim 1, wherein a gate is led out of the vertical gate region.

8. The SOI CMOS device having a vertical gate structure of claim 1, wherein an NMOS protective layer is grown on the NMOS region, and a PMOS protective layer is grown on the PMOS region.

9. The SOI CMOS device having a vertical gate structure of claim 5, wherein the vertical gate region is vertically aligned with the NMOS trench and the PMOS trench.
